(19) United States
(12) Patent Application Publication
(10) Pub. No.: US 2021/0247323 A1
(43) Pub. Date: Aug. 12, 2021

(54) INSPECTION DEVICE AND INSPECTION METHOD

(71) Applicant: Lasertec Corporation, Yokohama-shi (JP)

(72) Inventors: Kiwamu TAKEHISA, Yokohama-shi (JP); Tsunehito KOHYAMA, Yokohama-shi (JP); Hiroki MIYAI, Yokohama-shi (JP); Haruhiko KUSUNOSE, Yokohama-shi (JP)

(73) Assignee: Lasertec Corporation, Yokohama-shi (JP)

(21) Appl. No.: 17/168,053

(22) Filed: Feb. 4, 2021

(30) Foreign Application Priority Data
Feb. 7, 2020 (JP) 2020-019487

(51) Int. Cl. G01N 21/88; G02B 5/10; G02B 17/08; G01N 21/956

(52) U.S. Cl. CPC G01N 21/8806; G02B 5/10; G01N 2201/0636; G01N 21/956; G01N 2021/95676; G02B 17/0848

(57) ABSTRACT

An inspection device according to the present disclosure includes a spheroidal mirror configured to reflect illumination light as convergent light, a plane mirror configured to reflect the illumination light incident as the convergent light and cause the reflected illumination light to be incident on an object of inspection as incident light, a projection optical system configured to focus reflected light of the incident light reflected by the object of inspection, and a detector configured to detect reflected light focused by the projection optical system, wherein an angle of incidence of an incident optical axis being an optical axis of the incident light on the object of inspection is greater than 6 [deg], an angle of reflection of a reflected optical axis being an optical axis of the reflected light on the object of inspection is greater than 6 [deg].

### CROSS REFERENCE TO RELATED APPLICATION

The present application claims priority to Japanese Patent Application No. 2020-019487 filed on Feb. 7, 2020. The entire contents of the above-listed application is hereby incorporated by reference for all purposes.

### BACKGROUND

The present disclosure relates to an inspection device and an inspection method and, for example, relates to an inspection device and an inspection method for detecting a defect of an EUV mask that is used in EUV Lithography (Extremely Ultraviolet Lithography) as a lithography process in a semiconductor manufacturing process. An EUV mask, which is an object of inspection, may be a patterned EUV mask in which a multilayer film and an absorber are placed on a board (which is called a substrate), and a pattern is formed on the absorber.

For lithography technology that is expected to achieve semiconductor die shrink, ArF Lithography using an ArF excimer laser with an exposure wavelength of 193 nm as an exposure light source is being applied for mass production. Further, immersion technology (which is called ArF immersion lithography) that fills a gap between an objective lens and a wafer in an exposure device with a fluid to enhance the resolution is also being applied for mass production. Furthermore, for further die shrink, various technological developments are under way toward the practical use of EUVL with an exposure wavelength of 13.5 nm.

FIG. 1 is a cross-sectional view illustrating the structure of an EUV mask. As shown in FIG. 1, the structure of an EUV mask 60 to be inspected is such that a multilayer film 62 for reflecting EUV light is formed on a substrate 61 made of low thermal expansion glass, for example. The multilayer film 62 generally has a structure in which dozens of layers of molybdenum and silicon are alternately stacked. This multilayer film 62 reflects as much as about 65% of EUV light with a wavelength of 13.5 nm when the angle of incidence is 6 [deg]. Setting the angle of incidence to 6 [deg] is specified as a requirement to maximize the reflectance in many EUV exposure devices.

In the EUV mask 60, on the multilayer film 62 is an absorber 63 that absorbs EUV light. Blanks are formed by patterning the absorber 63. Note that, however, between the absorber 63 and the multilayer film 62 is a protective film 64 (which is a film called a buffer layer and a capping layer). For practical application to exposure, a pattern is formed on the absorber 63 by a resist process. A patterned EUV mask 60 is thereby produced.

The unacceptable size of a defect in the EUV mask 60 is significantly smaller than that in the existing ArF mask, and it is not easily detectable. Therefore, an actinic inspection that conducts an inspection using illumination light with the same wavelength as the exposure light with a wavelength of 13.5 nm is necessary for a pattern inspection. Note that an actinic inspection device intended for blanks of the EUV mask 60 is described in Anna Tchikoulaeva, et. al., “EUV actinic blank inspection: from prototype to production”, SPIE Vol. 8679, 2013, for example.

In a basic structure of an inspection device for the EUV mask 60, EUV light taken from an EUV light source is guided to the EUV mask 60 by an illumination optical system composed only of multilayer mirrors for EUV (which are hereinafter referred to simply as mirrors) to illuminate a minute inspection area on a mask surface of the EUV mask 60. Reflected light that is reflected by the pattern of the EUV mask 60 in this inspection area is collected by a projection optical system composed only of mirrors and projected (an image is formed) on the surface of a two-dimensional image sensor of a CCD camera or a TDI (Time Delay Integration) camera. Then, the pattern observed from the reflected light is analyzed to determine whether the pattern is correct or not. A pattern inspection of the EUV mask 60 is performed in this manner.

Generally, an EUV light source generates EUV light from micro plasma. Thus, the illumination optical system of the inspection device for the EUV mask 60 preferably has a structure that projects a bright point in micro plasma on the inspection area on the mask surface of the EUV mask 60. However, since only a mirror can be used for the illumination optical system, an optical system that uses one or two rotational spheroidal mirrors (which are hereinafter referred to simply as spheroidal mirrors) is employed.

This is because one spheroidal mirror has two focal points, and light generated at one focal point is focused on the other focal point. Thus, the EUV light source, the spheroidal mirror, and the EUV mask 60 are arranged so that one focal point corresponds to a bright point of the plasma, and the other focal point corresponds to a minute inspection area in the EUV mask 60. This allows EUV light to be guided to the minute inspection area and illuminate this area. Note that an EUV light source is described in EUV Source development for AIMS and Blank Inspection, SPIE Vol. 7636, p. 8, 2010, and High-brightness LPP source for actinic mask inspection, SPIE Vol. p. 7969, 2011, for example.

Further, an actinic inspection illuminates the EUV mask 60 with illumination light at an angle of incidence of 6 [deg], just like the case of illuminating the EUV mask 60 by an EUV exposure device. This enables observing an optical image similar to an optical image formed on a wafer surface by the EUV exposure device.

### SUMMARY

FIG. 2 is a view illustrating incident light on an object of inspection and reflected light from the object of inspection. As shown in FIG. 2, illumination light generated in a light source is reflected by a plane mirror 23 and illuminates an inspection object 50 such as the EUV mask 60 as incident light E4. Reflected light E5 reflected by the inspection object 50 is reflected by a concave mirror 31a and a spherical mirror 31b, and further passes though two or three mirrors and reaches a detector, though not shown.

To set the angle of incidence of an optical axis OX1 of the incident light E4 on the EUV mask 60 to 6 [deg], which is the same as in an EUV exposure device, the half-angle of a convergent beam for focusing the incident light E4 on the inspection area of the mask surface needs to be equal to or smaller than 6 [deg] (±6 [deg]). The incident light E4 to become a convergent beam illuminates the inspection object 50. The half-angle of the incident light E4 (which is referred to as the half-angle of incidence) and the half-angle of the reflected light E5 (which is referred to as a half-angle of reflection) are defined as follows.

When illumination light that illuminates the inspection object 50 such as the EUV mask 60 is the incident light E4, and light that is obtained when the incident light E4 is reflected on the inspection object 50 is the reflected light E5, the half-angle of incidence is the angle between the optical axis OX1 of the incident light E4 and the outer edge of the incident light E4 in an optical axis plane containing the optical axis OX1 of the incident light E4 and an optical axis OX2 of the reflected light E5. The optical axis plane is a paper plane in FIG. 2.

On the other hand, the half-angle of reflection of the spreading reflected light E5 obtained when the incident light E4 is reflected on the inspection object 50 and guided to a detector by a projection optical system is the angle between the optical axis OX2 of the reflected light E5 and the outer edge of the reflected light E5 in the optical axis plane. Note that the reflected light E5 contains light other than regular reflection light, such as diffuse reflected light and diffracted light.

FIG. 3 is a view illustrating the cross section of the reflected light E5 shown overlapping the reflecting surface of the concave mirror 31a. FIG. 3 also shows the state where the incident light E4 is virtually placed on the reflected light E5 side. As shown in FIG. 3, the numerical aperture (which is hereinafter referred to as NA) of the concave mirror 31a is 0.30, for example. In bright field observation, the reflecting surface that is physically available is half the area of the concave mirror 31a.

The NA of the incident light E4 in the illumination optical system is represented by the following equation (1).

The NA of the incident light E4 in the illumination optical system=sin (half-angle of incidence) (1)

When the half-angle of incidence of the incident light E4 of the convergent beam is 6 [deg], the NA of the illumination optical system is approximately 0.105.

On the other hand, the NA of the reflected light E5 in the projection optical system for forming an image of an inspection area of an inspection object on a sensor surface of a detector is represented by the following equation (2).

The NA of the reflected light E5 in the projection optical system=sin (half-angle of reflection) (2)

The NA of the reflected light E5 in the projection optical system is set to about 0.15, for example. As the NA of the projection optical system is greater, the resolution is higher. However, if the NA of the projection optical system is 0.2 or more, it is difficult to suppress an increase in aberration in terms of design and production. Thus, in practice, the NA of the projection optical system is set to 0.15 to 0.16. It is set to about 0.16 at maximum. According to U.S. Pat. No. 8,553,217, the NA of the projection optical system is 0.16.

The following Table 1 is a table showing an example of the half-angle of the incident light E4 (half-angle of incidence), the NA of the illumination optical system, the half-angle of the reflected light E5 (half-angle of reflection), the NA of the projection optical system, and the approximate number of a sigma value.

TABLE 1

| Half-Angle | NA of | Half-Angle of | NA of | |
|---|---|---|---|---|
| of Incident | Illumination | Reflected | Projection | Sigma |
| Light [deg] | Optical System | Light [deg] | Optical System | Value |
| 6 | 0.10 | 8.6 | 0.15 | 0.67 |
| 6 | 0.10 | 9.2 | 0.16 | 0.63 |
| 6 | 0.10 | 9.8 | 0.17 | 0.59 |
| 6 | 0.10 | 11.5 | 0.20 | 0.50 |

As shown in Table 1, when the NA of the projection optical system is set to 0.15 to 0.20, the proportion of the NA of the illumination optical system to the NA of the projection optical system is 0.5 to 0.67. The proportion of the NA of the illumination optical system to the NA of the projection optical system is referred to hereinafter as a sigma value.

FIG. 4 is a graph illustrating a pattern shape when the reflected light E5 reflected by the pattern with a width of 1.0 [μm] formed on a mask surface is detected by a detector in the case where a sigma value is 0.70. The horizontal axis indicates a position on the mask surface, and the vertical axis indicates the height of the pattern calculated from the reflected light E5. As shown in FIG. 4, when the sigma value is 0.70, the shape projects upward like a spike from the edge of the pattern in a projection image. It is known that such a spike shape is steep when the sigma value is 0.70 or less. Particularly, when conducting a comparative inspection with a reference specimen by using a pattern inspection device, it is difficult to make their spike shapes completely coincide with each other, and it is likely to be recognized that there is a defect in a spike part. Specifically, even when there is no defect in the pattern, it is recognized that the pattern has a defect, which is called a false defect and can occur in large amounts, causing a problem.

The present disclosure has been accomplished to solve the above problems and an object of the present disclosure is thus to provide an inspection device and an inspection method capable of suppressing the occurrence of false defects and improving inspection accuracy in a pattern inspection of the EUV mask 60.

An inspection device according to one aspect of the embodiment includes a spheroidal mirror configured to reflect illumination light as convergent light, a plane mirror configured to reflect the illumination light incident as the convergent light, and cause the reflected illumination light to be incident on an object of inspection as incident light, a projection optical system configured to focus reflected light of the incident light reflected by the object of inspection, and a detector configured to detect reflected light focused by the projection optical system, wherein an angle of incidence of an incident optical axis being an optical axis of the incident light on the object of inspection is greater than 6 [deg], an angle of reflection of a reflected optical axis being an optical axis of the reflected light on the object of inspection is greater than 6 [deg], in an optical axis plane containing the incident optical axis and the reflected optical axis, a half-angle of incidence between the incident optical axis and an outer edge of the incident light is greater than 6 [deg] and equal to or smaller than the angle of incidence, and a half-angle of reflection between the reflected optical axis and an outer edge of the reflected light is greater than 6 [deg] and equal to or smaller than the angle of reflection.

In the above-described inspection device, the angle of incidence may be equal to or greater than 7 [deg] and equal to or smaller than 9 [deg], and the half-angle of incidence may be equal to or greater than 7 [deg] and equal to or smaller than the angle of incidence.

The above-described inspection device may further include an incident-side aperture placed between the plane mirror and the object of inspection, the incident-side aperture may have an incident hole for the incident light to pass through, and the outer edge of the incident light may be formed by an edge of the incident hole.

In the above-described inspection device, the projection optical system may include a concave mirror configured to reflect the reflected light from the object of inspection, and a spherical mirror configured to reflect the reflected light reflected by the concave mirror, the inspection device may further include a reflection-side aperture placed between the concave mirror and the object of inspection, the reflection-side aperture may have a reflection hole for the reflected light to pass through, and the outer edge of the reflected light may be formed by an edge of the reflection hole.

In the above-described inspection device, a pattern formed on the object of inspection may be inspected by a comparative inspection comparing a reference specimen to the object of inspection.

An inspection method according to one aspect of the embodiment includes a step of reflecting illumination light as convergent light by a spheroidal mirror, a step of making the illumination light incident on a plane mirror as convergent light, and making the illumination light reflected by the plane mirror incident on an object of inspection as incident light, where an angle of incidence of an incident optical axis being an optical axis of the incident light on the object of inspection is greater than 6 [deg], a step of focusing reflected light of the illumination light reflected on the object of inspection by a projection optical system, where an angle of reflection of a reflected optical axis being an optical axis of the reflected light on the object of inspection is greater than 6 [deg], and a step of detecting, by a detector, the reflected light focused by the projection optical system, wherein in an optical axis plane containing the incident optical axis and the reflected optical axis, a half-angle of incidence between the incident optical axis and an outer edge of the incident light is greater than 6 [deg] and equal to or smaller than the angle of incidence, and a half-angle of reflection between the reflected optical axis and an outer edge of the reflected light is greater than 6 [deg] and equal to or smaller than the angle of reflection.

In the above-described inspection method, the angle of incidence may be equal to or greater than 7 [deg] and equal to or smaller than 9 [deg], and the half-angle of incidence may be equal to or greater than 7 [deg] and equal to or smaller than the angle of incidence.

In the above-described inspection method, the step of making the illumination light incident may make the incident light pass through an incident hole of an incident-side aperture placed between the plane mirror and the object of inspection, and thereby form the outer edge of the incident light by an edge of the incident hole.

In the above-described inspection method, the projection optical system may include a concave mirror configured to reflect the reflected light from the object of inspection, and a spherical mirror configured to reflect the reflected light reflected by the concave mirror, and the step of focusing may make the reflected light pass through a reflection hole of a reflection-side aperture placed between the concave mirror and the object of inspection, and thereby form the outer edge of the reflected light by an edge of the reflection hole.

The above-described inspection method may further include a step of inspecting a reference specimen, and a pattern formed on the object of inspection may be inspected by a comparative inspection comparing the reference specimen to the object of inspection.

According to the present disclosure, there are provided an inspection device and an inspection method capable of improving inspection accuracy.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF FIGURES

FIG. 1 is a cross-sectional view illustrating the structure of an EUV mask;

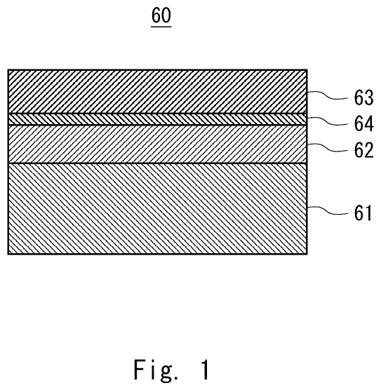

FIG. 2 is a view illustrating incident light on an object of inspection and reflected light from the object of inspection;

FIG. 3 is a view illustrating the cross section of reflected light shown overlapping a reflecting surface of a concave mirror;

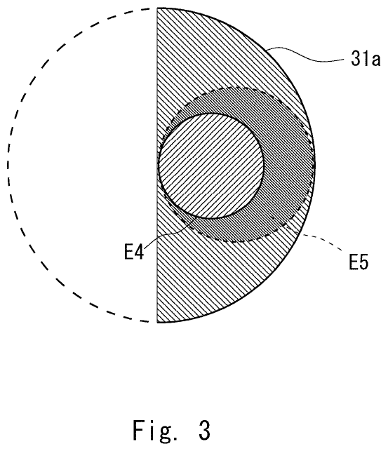

FIG. 4 is a graph illustrating a pattern shape when reflected light reflected by a pattern with a width of 1.0 [μm] formed on a mask surface is detected by a detector in the case where a sigma value is 0.70, where the horizontal axis indicates a position on the mask surface, and the vertical axis indicates the height of the pattern calculated from the reflected light;

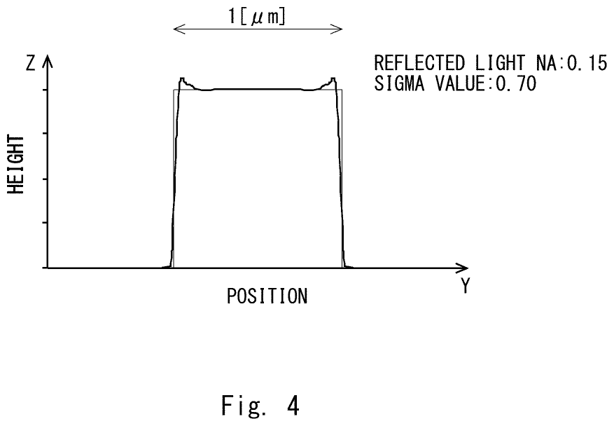

FIG. 5 is a block diagram illustrating an inspection device according to an embodiment;

FIG. 6 is a view illustrating the cross section of reflected light shown overlapping a reflecting surface of a concave mirror in the inspection device according to the embodiment;

FIG. 7 is a graph illustrating a pattern shape when reflected light reflected by a pattern with a width of 1.0 [μm] formed on a mask surface is detected by a detector in the case where a sigma value is 0.81 in the inspection device according to the embodiment, where the horizontal axis indicates a position on the mask surface, and the vertical axis indicates the height of the pattern calculated from the reflected light;

FIG. 8 is a graph illustrating a pattern shape when reflected light reflected by a pattern with a width of 1.0 [μm] formed on a mask surface is detected by a detector in the case where a sigma value is 0.93 in the inspection device according to the embodiment, where the horizontal axis indicates a position on the mask surface, and the vertical axis indicates the height of the pattern calculated from the reflected light;

FIG. 9 is a graph illustrating the incident angle dependence of reflectance in a multilayer film of an EUV mask, where the horizontal axis indicates the angle of incidence, and the vertical axis indicates the reflectance;

FIG. 10 is a graph illustrating the incident angle dependence of reflectance in a multilayer film of an EUV mask, where the horizontal axis indicates the angle of incidence, and the vertical axis indicates the reflectance;

FIG. 11 is a graph illustrating the incident angle dependence of reflectance in a multilayer film of an EUV mask, where the horizontal axis indicates the angle of incidence, and the vertical axis indicates the reflectance;

FIGS. 12a-d are views illustrating the distribution, the average reflectance, and the relative quantity of light of reflected light when the angle of incidence and the half-angle of incidence of illumination light are varied between 6 and 9 [deg] in the inspection device according to the embodiment;

FIG. 13 is a plan view illustrating an aperture in the inspection device according to the embodiment;

FIG. 14 is a block diagram illustrating another projection optical system in the inspection device according to the embodiment;

FIG. 15 is a flowchart illustrating a measurement method according to an embodiment;

FIG. 16 is a view illustrating the cross section of reflected light shown overlapping a reflecting surface of a concave mirror according to a modified example of the embodiment; and

FIG. 17 is a view illustrating the cross section of reflected light shown overlapping a reflecting surface of a concave mirror according to a modified example of the embodiment.

### DETAILED DESCRIPTION

A specific structure of the present embodiment will be described hereinbelow with reference to the drawings. The explanation provided hereinbelow merely illustrates a preferred embodiment of the present disclosure, and the present disclosure is not limited to the below-described embodiment. In the following description, the identical reference symbols denote substantially identical elements.

### Embodiment

An inspection device and an inspection method according to an embodiment are described hereinafter. The structure of the inspection device according to the embodiment is described first. The inspection method using the inspection device according to the embodiment is described after that.

### Structure of Inspection Device

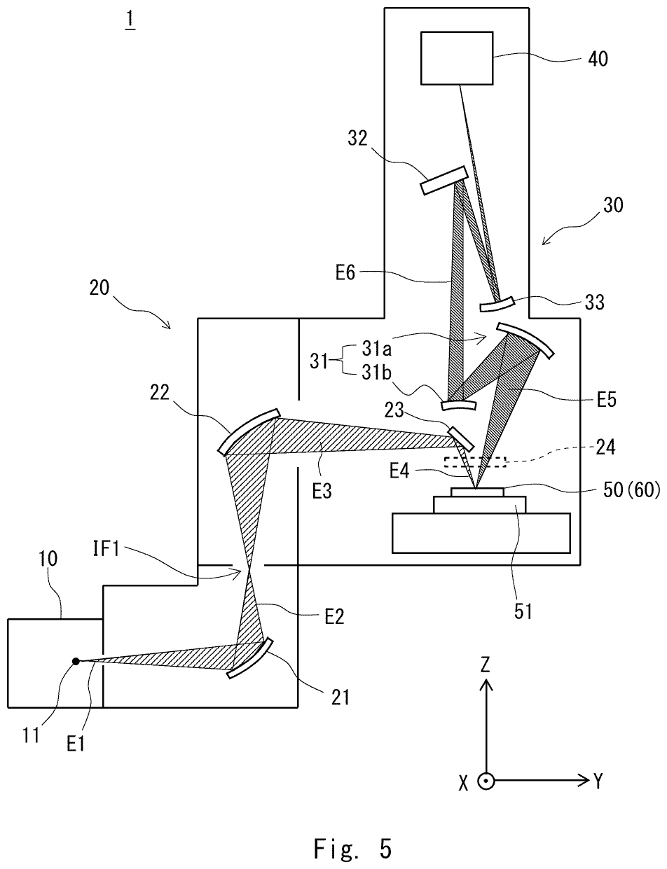

FIG. 5 is a block diagram illustrating an inspection device according to a first embodiment. As shown in FIG. 5, an inspection device 1 inspects a pattern of the EUV mask 60, for example, as the inspection object 50. The inspection device 1 includes a light source 10, an illumination optical system 20, a projection optical system 30, and a detector 40.

The light source 10 generates illumination light E1. The light source 10 includes a plasma 11 that generates EUV light as the illumination light E1, for example. The light source 10 may be an LPP light source. Note that the illumination light E1 may include UV light, visible light and the like, not limited to EUV light.

The illumination optical system 20 includes a spheroidal mirror 21, a spheroidal mirror 22, and a plane mirror 23. The illumination optical system 20 allows the illumination light E1 taken from the light source 10 to illuminate the inspection object 50 through the spheroidal mirror 21 and the spheroidal mirror 22. The spheroidal mirror 21 reflects the illumination light E1 taken from the light source 10 and focuses the light at a light concentration point IF1. The light concentration point IF1 is also referred to as an intermediate focus. The light concentration point IF1 is one focal point of two focal points of the spheroidal mirror 21. The plasma 11 is located at the other focal point of the two focal points of the spheroidal mirror 21.

The spheroidal mirror 22 reflects and focuses illumination light E2 that has focused at the light concentration point IF1 and spreads from the light concentration point IF1. To be specific, the spheroidal mirror 22 receives the illumination light E2 and reflects illumination light E3 that converges like a cone as convergent light. The light concentration point IF1 is located at one focal point of two focal points of the spheroidal mirror 22.

The plane mirror 23 reflects the illumination light E3 as the convergent light reflected by the spheroidal mirror 22. To be specific, the plane mirror 23 reflects the illumination light E3 that is incident as the convergent light, and allows the reflected illumination light to be incident on the inspection object 50 as incident light E4. The plane mirror 23 thereby focuses the reflected illumination light on the inspection object 50. The plane mirror 23 allows the incident light E4 to be illuminated on the inspection area of the inspection object 50 by a beam that converges like a cone.

The EUV mask 60 as the inspection object 50 is placed on a stage 51. The stage 51 is an XYZ stage that is movable in the x-axis direction and the y-axis direction. Note that the stage 51 may be movable in the z-axis direction. An illumination area in which the inspection object 50 is illuminated with the incident light E4 covers an inspection area. Reflected light E5 reflected by the inspection object 50 in the illumination area contains regular reflection light of the regular reflection light, and light other than regular reflection light, such as diffracted light. Thus, the reflected light E5 reflected by the inspection object 50 contains pattern information of the inspection area.

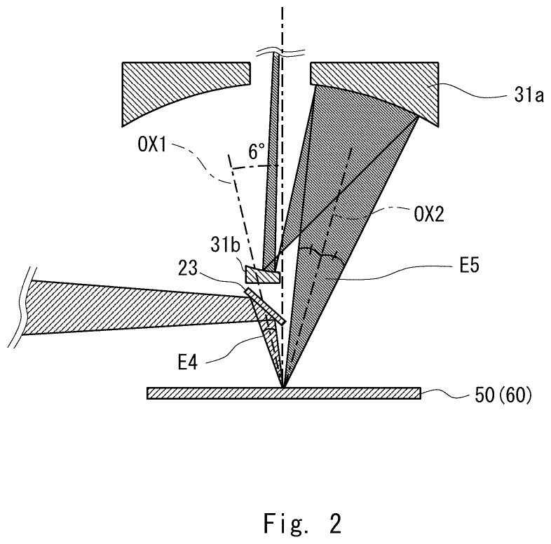

As shown in FIGS. 2 and 5, in the inspection device 1 according to this embodiment, the angle of incidence of an incident optical axis, which is the optical axis OX1 of the incident light E4 (which is hereinafter referred to as the angle of incidence of incident light), on the inspection object 50 is greater than 6 [deg]. The angle of reflection of a reflected optical axis, which is the optical axis OX2 of the reflected light (which is hereinafter referred to as the angle of reflection of reflected light), on the inspection object 50 is greater than 6 [deg]. In the optical axis plane containing the incident optical axis and the reflected optical axis, the half-angle of incidence between the incident optical axis and the outer edge of the incident light E4 is greater than 6 [deg] and equal to or smaller than the angle of incidence. The half-angle of reflection between the reflected optical axis and the outer edge of the reflected light E5 is greater than 6 [deg] and equal to or smaller than the angle of reflection. This allows the sigma value to be larger than 0.7 and thereby suppresses the occurrence of false defects.

To be specific, the angle of incidence of the incident light E4 is greater than 6 [deg] and equal to or smaller than 9 [deg], and the half-angle of incidence is greater than 6 [deg] and equal to or smaller than the angle of incidence. More preferably, the angle of incidence of the incident light E4 is equal to or greater than 7 [deg] and equal to or smaller than 9 [deg], and the half-angle of incidence is equal to or greater than 7 [deg] and equal to or smaller than the angle of incidence. Further, the angle of reflection of the reflected light E5 is greater than 6 [deg] and equal to or smaller than 9 [deg], and the half-angle of reflection is greater than 6 [deg] and equal to or smaller than the angle of reflection. More preferably, the angle of reflection of the reflected light E5 is equal to or larger than 7 [deg] and equal to or smaller than 9 [deg], and the half-angle of reflection is equal to or greater than 7 [deg] and equal to or smaller than the angle of reflection.

Increasing the angle of incidence of the incident light E4 to be greater than 6 [deg] is achieved by design of the shape, arrangement and the like of the spheroidal mirrors 21 and 22 and the plane mirror 23 in the illumination optical system 20. Increasing the half-angle of incidence to be greater than 6 [deg] is achieved by design of the illumination optical system 20 as described above and also achieved by design of the take-off angle when taking the illumination light E1 from the light source 10.

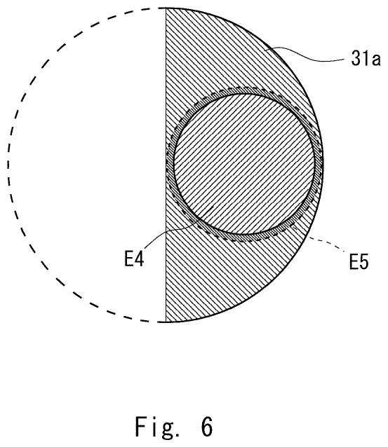

FIG. 6 is a view illustrating the cross section of the reflected light E5 shown overlapping the reflecting surface of the concave mirror 31a in the inspection device 1 according to this embodiment. FIG. 6 also shows the state where the incident light E4 is virtually placed on the reflected light E5 side. As shown in FIG. 6, in the inspection device 1 according to this embodiment, the NA of the incident light E4 in the illumination optical system 20 is set to as large as about 0.15, which is at the same level as the NA of the reflected light E5.

Table 2 is a table showing an example of the half-angle of the incident light E4 (half-angle of incidence), the NA of the illumination optical system, the half-angle of the reflected light E5 (half-angle of reflection), the NA of the projection optical system, and the approximate number of a sigma value.

TABLE 2

| Half-Angle | NA of | Half-Angle of | NA of | |
|---|---|---|---|---|
| of Incident | Illumination | Reflected | Projection | Sigma |
| Light [deg] | Optical System | Light [deg] | Optical System | Value |
| 7 | 0.12 | 8.6 | 0.15 | 0.81 |
| 7 | 0.12 | 9.2 | 0.16 | 0.75 |
| 7 | 0.12 | 9.8 | 0.17 | 0.71 |
| 7 | 0.12 | 11.5 | 0.20 | 0.60 |
| 8 | 0.14 | 8.6 | 0.15 | 0.93 |
| 8 | 0.14 | 9.2 | 0.16 | 0.86 |
| 8 | 0.14 | 9.8 | 0.17 | 0.82 |
| 8 | 0.14 | 11.5 | 0.20 | 0.70 |
| 9 | 0.16 | 9.8 | 0.17 | 0.94 |
| 9 | 0.16 | 11.5 | 0.20 | 0.80 |

As shown in Table 2, by setting the angle of incidence of the incident light E4 to 7 [deg], the half-angle of incidence becomes 7 [deg]. In this case, the NA of the angle of incidence in the illumination optical system 20 is 0.12. When the NA of the reflected light E5 in the projection optical system 30 is set to 0.15, 0.16, 0.17 and 0.20, the sigma value is 0.81, 0.75, 0.71 and 0.60, respectively. Since the NA of the reflected light E5 in the projection optical system 30 is set to about 0.15 to 0.17 as described earlier, the sigma value is greater than 0.7, which suppresses the occurrence of false defects.

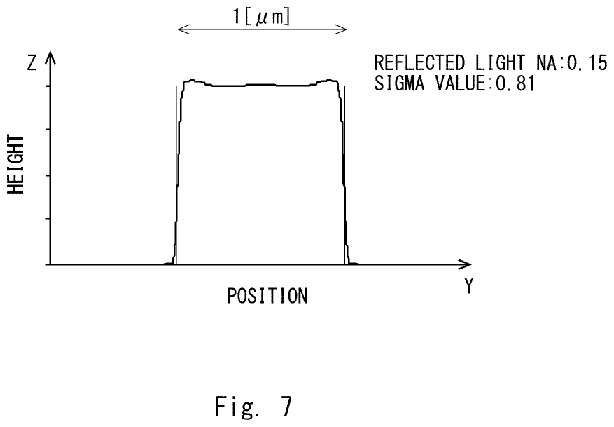

FIG. 7 is a graph illustrating a pattern shape when the reflected light E5 reflected by a pattern with a width of 1.0 [μm] formed on a mask surface is detected by the detector 40 in the case where the sigma value is 0.81 in the inspection device 1 according to the embodiment, where the horizontal axis indicates a position on the mask surface, and the vertical axis indicates the height of the pattern calculated from the reflected light. As shown in FIG. 7, when the sigma value is 0.81, the shape projecting upward like a spike from the edge of the pattern in a projection image becomes smaller, which reduces false defects occurring at the edge part.

By setting the angle of incidence of the incident light E4 to 8 [deg], the half-angle of incidence becomes 8 [deg]. In this case, the NA of the angle of incidence in the illumination optical system 20 is 0.14. When the NA of the reflected light E5 in the projection optical system 30 is set to 0.15, 0.16, 0.17 and 0.20, the sigma value is 0.93, 0.86, 0.82 and 0.70, respectively. By setting the NA of the reflected light E5 to about 0.15 to 0.17, the sigma value is greater than 0.7, which suppresses the occurrence of false defects.

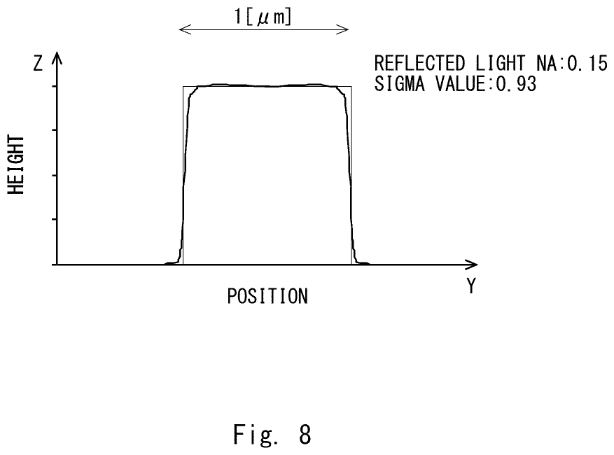

FIG. 8 is a graph illustrating a pattern shape when the reflected light E5 reflected by a pattern with a width of 1.0 [μm] formed on a mask surface is detected by the detector in the case where the sigma value is 0.93 in the inspection device according to the embodiment, where the horizontal axis indicates a position on the mask surface, and the vertical axis indicates the height of the pattern calculated from the reflected light. As shown in FIG. 8, when the sigma value is 0.93, the shape projecting upward like a spike from the edge of the pattern in a projection image becomes even smaller, which significantly reduces false defects occurring at the edge part.

By setting the angle of incidence of the incident light to 9 [deg], the half-angle of incidence becomes 9 [deg]. In this case, the NA of the incident light E4 in the illumination optical system 20 is 0.16. When the NA of the reflected light E5 in the projection optical system 30 is set to 0.17 and 0.20, the sigma value is 0.94 and 0.80, respectively. By setting the NA of the reflected light to about 0.17, the sigma value is greater than 0.7, which suppresses the occurrence of false defects.

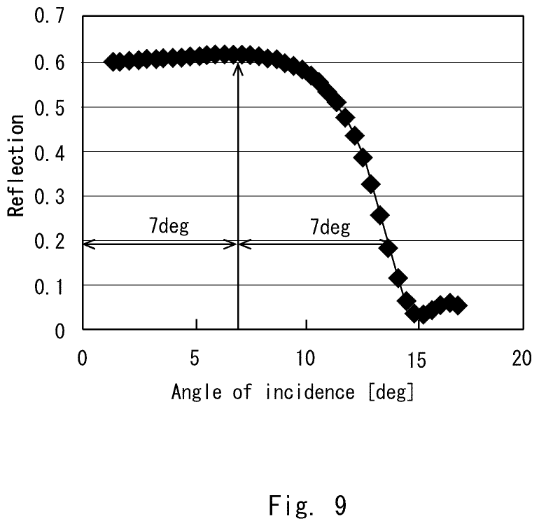

FIGS. 9 to 11 are graphs illustrating the incident angle dependence of reflectance in the multilayer film 62 of the EUV mask 60, where the horizontal axis indicates the angle of incidence, and the vertical axis indicates the reflectance.

As shown in FIG. 9, the multilayer film 62 of the EUV mask 60 has specifications that its reflectance is highest when the angle of incidence of the incident light E4 is 6 [deg]. In the multilayer film 62 having such specifications, the reflectance of the reflected light E5 is not largely reduced when the angle of incidence is 7 [deg].

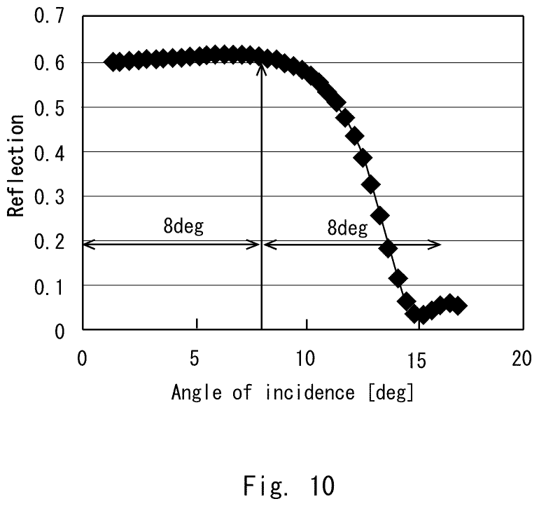

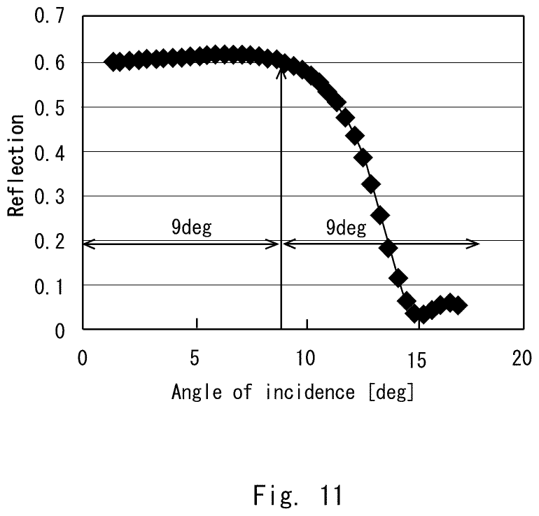

As shown in FIGS. 10 and 11, in the multilayer film 62 whose reflectance is highest when the angle of incidence of the incident light E4 is 6 [deg], the reflectance of the reflected light E5 is not largely reduced when the angle of incidence is 8 [deg] and 9 [deg]. However, when the angle of incidence is greater than 9 [deg], the reflectance of the reflected light E5 is significantly reduced. Thus, the angle of incidence and the half-angle of incidence of the incident light E4 are preferably in the range of 7.0 [deg] to 9.0 [deg].

As shown in FIG. 11, when the angle of incidence and the half-angle of incidence of the incident light E4 are 9.0 [deg], the incident light E4 contains light that is incident on the inspection object 50 at an angle of 0 to 18 [deg]. Thus, the incident light E4 contains light that is incident at an angle of 12 [deg] or higher, which can cause a decrease in the quantity of the reflected light E5. However, in practice, the intensity distribution of the incident light E4 is a Gaussian distribution where there are an overwhelming number of components that are incident on the inspection object 50 at the same angle as the optical axis tilted by 9 [deg]. In addition, the quantity of the reflected light E5 is large because it contains light that is incident at angles in a wide range of 0 to 18 [deg]. This is described in the following figures.

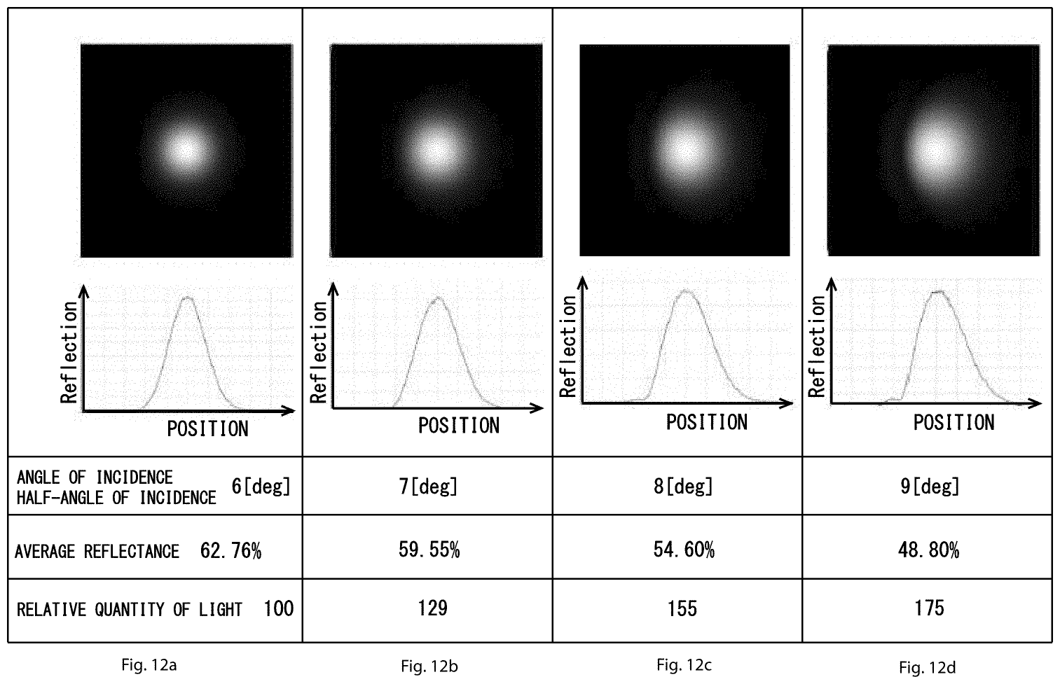

FIGS. 12a-d are views illustrating the distribution, the average reflectance, and the relative quantity of light of reflected light when the angle of incidence and the half-angle of incidence of the incident light E4 are varied between 6 and 9 [deg] in the inspection device according to the embodiment.

As shown in FIGS. 12a-d, when the angle of incidence and the half-angle of incidence of the incident light E4 are 6 [deg], the intensity of the reflected light E5 forms a Gaussian distribution. The average reflectance is 62.76%. The average reflectance is the reflectance based on the assumption that the maximum reflectance in the multilayer film 62 whose reflectance is highest when the angle of incidence of the incident light E4 is 6 [deg] is 65.0%. The relative quantity of light in consideration of the half-angle of incidence is 100. The quantity of light when the angle of incidence and the half-angle of incidence of the incident light E4 are 6 [deg] is a reference of the relative quantity of light at the following half-angles of incidence.

When the angle of incidence and the half-angle of incidence of the incident light E4 are 7 [deg], the intensity of the reflected light forms a Gaussian distribution. The average reflectance is 59.55%. The relative quantity of light is 129. When the angle of incidence and the half-angle of incidence of the incident light E4 are 8 [deg], the intensity of the reflected light forms a Gaussian distribution. The average reflectance is 54.6%. The relative quantity of light is 155. When the angle of incidence and the half-angle of incidence of the incident light E4 are 9 [deg], the intensity of the reflected light is slightly deviated from a Gaussian distribution. Specifically, the intensity on one side is reduced. The average reflectance is 48.8%. The relative quantity of light is 175.

As shown in FIGS. 12a-d, when the quantity of reflected light is three-dimensionally taken into consideration, the quantity of the reflected light E5 is larger as the angle of incidence is greater until the angle of incidence reaches 9 [deg].

Referring back to FIG. 5, the projection optical system 30 includes a Schwarzschild optical system 31, a reflecting mirror 32, and a reflecting mirror 33. The projection optical system 30 focuses the reflected light E5 obtained when the incident light E4 is reflected on the inspection object 50.

The Schwarzschild optical system 31 is composed of a concave mirror 31a and a spherical mirror 31b. The spherical mirror 31b is a convex mirror, for example. The Schwarzschild optical system 31 composed of the concave mirror 31a and the spherical mirror 31b is an enlargement optical system. The concave mirror 31a reflects the reflected light E5 from the inspection object 50. The spherical mirror 31b reflects the reflected light E5 reflected by the concave mirror 31a. The reflecting mirror 32 and the reflecting mirror 33 reflect light E6 reflected by the spherical mirror 31b and guide it to the detector 40. The reflecting mirror 32 is a plane mirror, for example. The plane mirror is a concave mirror, for example.

The detector 40 detects reflected light E6 focused by the projection optical system 30. The detector 40 is a TDI camera, for example. When the detector 40 is a TDI camera, the reflected light E6 from the inspection object 50 may be detected, moving the inspection object 50 in a predetermined scan direction in a plane parallel to the inspection surface of the inspection object 50 with respect to the incident light E4 for illuminating the inspection object 50. The scan direction is the y-axis direction, for example. The detector 40 then acquires an image of the inspection object 50.

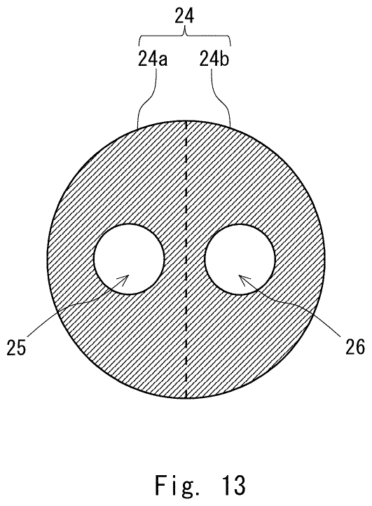

FIG. 13 is a plan view illustrating an aperture 24 in the inspection device 1 according to this embodiment. As shown in FIGS. 5 and 13, the inspection device 1 may include the aperture 24. The aperture 24 may be divided into an incident-side aperture 24a and a reflection-side aperture 24b, or the incident-side aperture 24a and the reflection-side aperture 24b may be integrated together.

The incident-side aperture 24a is placed between the plane mirror 23 and the inspection object 50. The incident-side aperture 24a has an incident hole 25 for the incident light E4 to pass through. The outer edge of the incident light E4 is formed by the edge of the incident hole 25.

The reflection-side aperture 24b is placed between the concave mirror 31a and the inspection object 50. The reflection-side aperture 24b has a reflection hole 26 for the reflected light E5 to pass through. The outer edge of the reflected light E5 is formed by the edge of the reflection hole 26. With the aperture 24, the outer edges of the incident light E4 and the reflected light E5 are clarified. This enables accurately determining the half-angle of incidence and the half-angle of reflection. Further, this enables cutting off the edges of the incident light E4 and the reflected light E5 where the quantity of light is reduced.

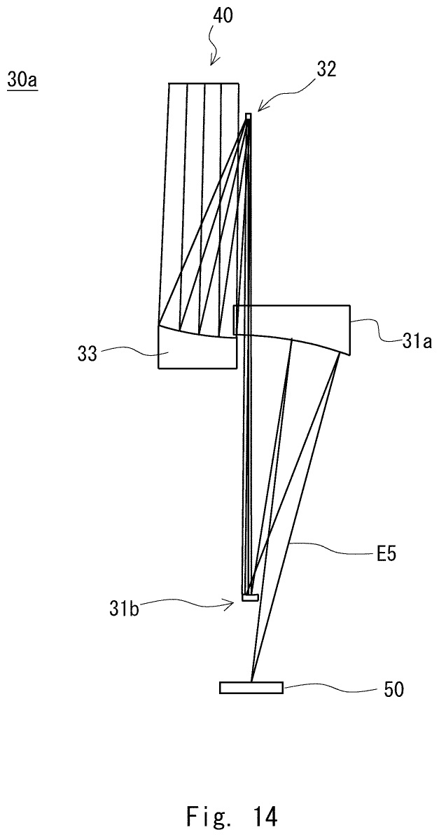

FIG. 14 is a block diagram illustrating another projection optical system 30a in the inspection device 1 according to the embodiment. As shown in FIG. 14, the spherical mirror 31b and the reflecting mirror 33 may be concave mirrors. Further, the reflecting mirror 32 may be a convex mirror. In this structure also, the reflected light E5 can be focused and guided to the detector 40.

### Inspection Method

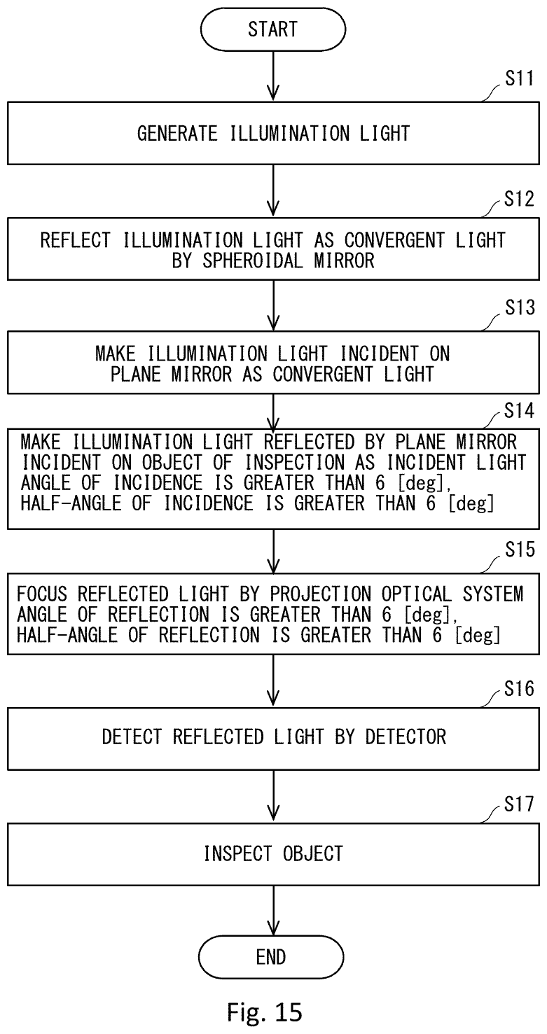

An inspection method using the inspection device 1 according to this embodiment is described hereinafter. FIG. 15 is a flowchart illustrating the measurement method according to this embodiment.

As shown in Step S11 of FIG. 15, illumination light is generated first. For example, the illumination light E1 is generated by the light source 10. The light source 10 includes the plasma 11 that generates EUV light as the illumination light E1, for example.

Next, as shown in Step S12, the illumination light E3 is reflected as convergent light by the spheroidal mirror 21 and the spheroidal mirror 22. To be specific, the spheroidal mirror 21 reflects the illumination light E1 taken from the light source 10 and focuses it on the light concentration point IF1. The spheroidal mirror 22 reflects and focuses the illumination light E2 that has focused at the light concentration point IF1 and spreads from the light concentration point IF1. In this manner, the illumination light E3 is reflected as convergent light by the spheroidal mirror 22.

Then, as shown in Step S13, the illumination light E3 is incident on the plane mirror 23 as convergent light. The plane mirror 23 thereby reflects the illumination light E3, which is convergent light reflected by the spheroidal mirror 22.

Then, as shown in Step S14, the illumination light E3 reflected by the plane mirror 23 is incident on the inspection object 50 as the incident light E4. At this time, the angle of incidence of the incident light E4 is set to greater than 6 [deg]. Further, the half-angle of incidence between the incident optical axis and the outer edge of the incident light E4 is set to greater than 6 [deg]. Preferably, the angle of incidence of the incident light E4 is equal to or greater than 7 [deg] and equal to or smaller than 9 [deg], and the half-angle of incidence is equal to or greater than 7 [deg] and equal to or smaller than the angle of incidence.

Note that, when the illumination light is incident on the inspection object 50 as the incident light E4, the incident-side aperture 24a may be placed between the plane mirror 23 and the inspection object 50, so that the incident light E4 passes through the incident hole 25 of the incident-side aperture 24a. This allows the outer edge of the incident light E4 to be formed by the edge of the incident hole 25.

Then, as shown in Step S15, the reflected light E5 is focused by the projection optical system 30. At this time, the angle of reflection of the reflected light E5 is set to greater than 6 [deg]. Further, the half-angle of reflection between the reflected optical axis and the outer edge of the reflected light E5 is set to greater than 6 [deg]. Preferably, the angle of reflection of the reflected light E5 is equal to or greater than 7 [deg] and equal to or smaller than 9 [deg], and the half-angle of reflection is equal to or greater than 7 [deg] and equal to or smaller than the angle of reflection.

Note that, when the reflected light E5 is focused by the projection optical system 30, the reflection-side aperture 24b may be placed between the concave mirror 31a and the inspection object 50, so that the reflected light E5 passes through the reflection hole 26 of the reflection-side aperture 24b. This allows the outer edge of the reflected light E5 to be formed by the edge of the reflection hole 26.

Then, as shown in Step S16, the reflected light E6 focused by the projection optical system 30 is detected by the detector 40.

After that, as shown in Step S17, the inspection object 50 is inspected. For example, the process may further include a step of inspecting a reference specimen, and the inspection object 50 is inspected by a comparative inspection between the reference specimen and the inspection object 50. To be specific, a pattern inspection of the EUV mask 60 is conducted based on a comparative inspection between the reference specimen and the inspection object 50. The inspection object 50 is inspected in this manner.

The effects of this embodiment are described hereinafter. The inspection device 1 according to this embodiment sets the angle of incidence and the half-angle of incidence to greater than 6 [deg], and sets the angle of reflection and the half-angle of reflection to greater than 6 [deg]. This allows the sigma value to be larger than 0.7 and thereby suppresses the occurrence of false defects. The inspection accuracy is thereby improved.

Further, by setting the angle of incidence to be equal to or greater than 7 [deg] and equal to or smaller than 9 [deg], and setting the half-angle of incidence to be equal to or greater than 7 [deg] and equal to or smaller than the angle of incidence, the quantity of reflected light increases. The inspection accuracy is thereby improved. Further, the quantity of reflected light increases also by setting the angle of reflection to be equal to or greater than 7 [deg] and equal to or smaller than 9 [deg], and setting the half-angle of reflection to be equal to or greater than 7 [deg] and equal to or smaller than the angle of reflection. The inspection accuracy is thereby improved.

The incident light E4 and the reflected light E5 pass through the incident hole 25 and the incident hole 25, respectively, of the aperture 24. This enables accurately determining the half-angle of incidence and the half-angle of reflection. Further, this enables cutting off the edges of the incident light E4 and the reflected light E5 where the quantity of light is reduced, and thereby the inspection accuracy is improved.

### Modified Example

A modified example of the embodiment is described hereinafter. This modified example is an example in which NA is different between the x-axis direction and the y-axis direction. To be specific, in the above-described embodiment, the half-angle of incidence is defined as the angle between the optical axis OX1 of the incident light E4 and the outer edge of the incident light E4 in the optical axis plane. In this modified example, the angle between the optical axis OX1 of the incident light E4 and the outer edge of the incident light E4 in the optical axis plane is a first half-angle of incidence. Further, in the plane containing the optical axis OX1 of the incident light E4 and orthogonal to the optical axis plane, the angle between the optical axis OX1 and the outer edge of the incident light E4 is a second half-angle of incidence.

Then, NA in the y-axis direction, which is NAy, is represented by the following equation (3), and NA in the x-axis direction, which is NAx, is represented by the following equation (4).

NAx=sin(second half-angle of incidence) (3)

NAy=sin(first half-angle of incidence) (4)

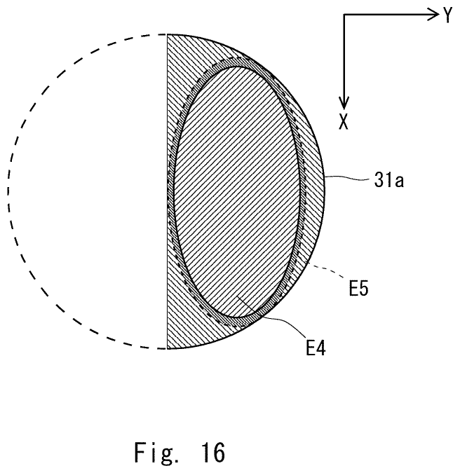

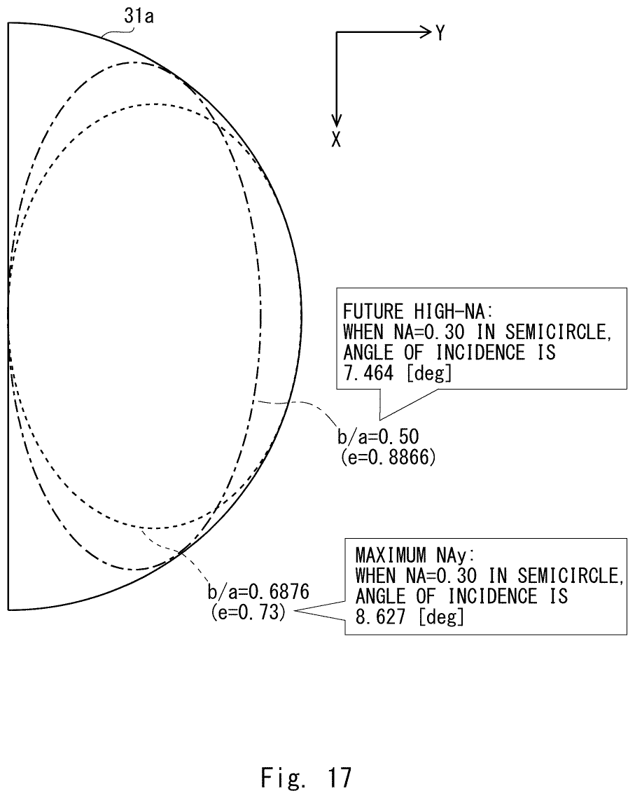

FIGS. 16 and 17 are views illustrating the cross section of the reflected light E5 shown overlapping the reflecting surface of the concave mirror 31a according to the modified example of the embodiment. FIG. 16 also shows the state where the incident light E4 is virtually placed on the reflected light E5 side. As shown in FIG. 16, in this modified example, NAx in the x-axis direction of the reflected light E5 in the projection optical system 30 is about 0.26, and NAy in the y-axis direction is about 0.13. In this case, the second half-angle of incidence is 15 [deg], and the first half-angle of incidence is 7.5 [deg].

The resolution of the inspection device 1 can be represented by the following equation (5), for example, where λ is the wavelength of the incident light E4.

Resolution=0.25×λ/NA (5)

Thus, the resolution increases as NA is larger. Particularly, in the EUV mask which is called the future high-NA generation, it is known that relative to the pattern size on a wafer, the size increases by four to eight times the current size only in the y-direction, which is the scan direction in the EUV exposure device. As a result, regarding the pattern of the EUV mask 60, die shrink by the evolution of the generation is achieved only in the x-direction. Thus, by setting NAx to be larger than NAy, a highly sensitive inspection can be conducted in the x-direction where die shrink is done in the pattern.

Thus, as shown in FIG. 17, for example, NAx is allowed to further increase while NAy is kept at 0.15, which is the maximum value for the concave mirror 31a, and the angle of incidence of the incident light E4 is 8.627 [deg]. Note that the cross section of the reflected light E5 at this time is an ellipse where the ratio b/a of the long axis b and the short axis a is 0.6876, and the eccentricity e is 0.73.

Particularly, if it is an ellipse where the ratio b/a of the long axis b and the short axis a is 0.5, and the eccentricity e is 0.8866, the resolution in the x-axis direction is twice that in the y-axis direction. The angle of incidence of the incident light E4 in this case is 7.464 [deg].

Setting the resolution in the x-axis direction to twice the resolution in the y-axis direction is particularly effective in a pattern inspection of the EUV mask in the high-NA generation. In the EUV mask in the high-NA generation, while the resolution remains four times in the x-axis direction, it is eight times in the y-axis direction, and the pattern size is twice different between the x-axis direction and the y-axis direction. Thus, as described earlier, by setting the resolution by NA to be twice different between the x-axis direction and the y-axis direction, the defect size at the detection limit is twice different, and therefore there is no need to make adjustment between the x-direction and the y-direction when detecting a killer defect proportional to the pattern size, and an inspection result can be used without any change.

Although embodiments of the present disclosure are described in the foregoing, the present disclosure involves appropriate modifications without impairment of its object and effects and is not restricted to the above-described embodiments.

The embodiment and the modified example can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

1. An inspection device comprising:
a spheroidal mirror configured to reflect illumination light as convergent light;
a plane mirror configured to reflect the illumination light incident as the convergent light, and cause the reflected illumination light to be incident on an object of inspection as incident light;
a projection optical system configured to focus reflected light of the incident light reflected by the object of inspection; and
a detector configured to detect reflected light focused by the projection optical system, wherein
an angle of incidence of an incident optical axis being an optical axis of the incident light on the object of inspection is greater than 6 [deg],
an angle of reflection of a reflected optical axis being an optical axis of the reflected light on the object of inspection is greater than 6 [deg],
in an optical axis plane containing the incident optical axis and the reflected optical axis,
a half-angle of incidence between the incident optical axis and an outer edge of the incident light is greater than 6 [deg] and equal to or smaller than the angle of incidence, and
a half-angle of reflection between the reflected optical axis and an outer edge of the reflected light is greater than 6 [deg] and equal to or smaller than the angle of reflection.

2. The inspection device according to claim 1, wherein
the angle of incidence is equal to or greater than 7 [deg] and equal to or smaller than 9 [deg], and
the half-angle of incidence is equal to or greater than 7 [deg] and equal to or smaller than the angle of incidence.

3. The inspection device according to claim 1, further comprising:
an incident-side aperture placed between the plane mirror and the object of inspection, wherein
the incident-side aperture has an incident hole for the incident light to pass through, and
the outer edge of the incident light is formed by an edge of the incident hole.

4. The inspection device according to claim 1, wherein
the projection optical system includes:
a concave mirror configured to reflect the reflected light from the object of inspection, and
a spherical mirror configured to reflect the reflected light reflected by the concave mirror,
the inspection device further comprises a reflection-side aperture placed between the concave mirror and the object of inspection,
the reflection-side aperture has a reflection hole for the reflected light to pass through, and
the outer edge of the reflected light is formed by an edge of the reflection hole.

5. The inspection device according to claim 1, wherein a pattern formed on the object of inspection is inspected by a comparative inspection comparing a reference specimen to the object of inspection.

6. The inspection device according to claim 1, further comprising:
an illumination optical system configured to include the spheroidal mirror and the plane mirror, and illuminate the object of inspection on which a pattern is formed with the illumination light through the spheroidal mirror and the plane mirror,
wherein a sigma value being a proportion of NA of the illumination optical system to NA of the projection optical system is greater than 0.7 and equal to or smaller than 0.94.

7. The inspection device according to claim 1, wherein
in an optical axis plane containing the incident optical axis and the reflected optical axis,
when the half-angle of incidence is a first half-angle of incidence, the first half-angle of incidence is greater than 6 [deg] and equal to or smaller than the angle of incidence,
in a plane containing the incident optical axis and orthogonal to the optical axis plane,
a second half-angle of incidence between the incident optical axis and the outer edge of the incident light is greater than 6 [deg] and equal to or smaller than the angle of incidence, and
NAx is greater than NAy when
NAx=sin (the second half-angle of incidence), and
NAy=sin (the first half-angle of incidence).

8. The inspection device according to claim 7, wherein
the projection optical system includes:
a concave mirror configured to reflect the reflected light from the object of inspection, and
a spherical mirror configured to reflect the reflected light reflected by the concave mirror,
the reflected light on a reflecting surface of the concave mirror is an ellipse, and
a proportion of a long axis to a short axis is approximately 0.5.

9. The inspection device according to claim 7, wherein
NAx is approximately twice NAy.

10. An inspection method comprising:
a step of reflecting illumination light as convergent light by a spheroidal mirror;
a step of making the illumination light incident on a plane mirror as convergent light, and making the illumination light reflected by the plane mirror incident on an object of inspection as incident light, where an angle of incidence of an incident optical axis being an optical axis of the incident light on the object of inspection is greater than 6 [deg];
a step of focusing reflected light of the illumination light reflected on the object of inspection by a projection optical system, where an angle of reflection of a reflected optical axis being an optical axis of the reflected light on the object of inspection is greater than 6 [deg]; and
a step of detecting, by a detector, the reflected light focused by the projection optical system, wherein
in an optical axis plane containing the incident optical axis and the reflected optical axis,
a half-angle of incidence between the incident optical axis and an outer edge of the incident light is greater than 6 [deg] and equal to or smaller than the angle of incidence, and
a half-angle of reflection between the reflected optical axis and an outer edge of the reflected light is greater than 6 [deg] and equal to or smaller than the angle of reflection.

11. The inspection method according to claim 10, wherein
the angle of incidence is equal to or greater than 7 [deg] and equal to or smaller than 9 [deg], and
the half-angle of incidence is equal to or greater than 7 [deg] and equal to or smaller than the angle of incidence.

12. The inspection method according to claim 10, wherein
the step of making the illumination light incident makes the incident light pass through an incident hole of an incident-side aperture placed between the plane mirror and the object of inspection, and thereby forms the outer edge of the incident light by an edge of the incident hole.

13. The inspection method according to claim 10, wherein
the projection optical system includes:
a concave mirror configured to reflect the reflected light from the object of inspection, and
a spherical mirror configured to reflect the reflected light reflected by the concave mirror, and
the step of focusing makes the reflected light pass through a reflection hole of a reflection-side aperture placed between the concave mirror and the object of inspection, and thereby forms the outer edge of the reflected light by an edge of the reflection hole.

14. The inspection method according to claim 10, further comprising:
a step of inspecting a reference specimen,
wherein a pattern formed on the object of inspection is inspected by a comparative inspection comparing the reference specimen to the object of inspection.

15. The inspection method according to claim 10, wherein
the step of reflecting the illumination light as convergent light by the spheroidal mirror reflects the illumination light as convergent light by the spheroidal mirror in an illumination optical system that illuminates an object of inspection on which a pattern is formed with the illumination light through the spheroidal mirror and the plane mirror, and
a sigma value being a proportion of NA of the illumination optical system to NA of the projection optical system is greater than 0.7 and equal to or smaller than 0.94.

16. The inspection method according to claim 10, wherein
in an optical axis plane containing the incident optical axis and the reflected optical axis,
when the half-angle of incidence is a first half-angle of incidence, the first half-angle of incidence is greater than 6 [deg] and equal to or smaller than the angle of incidence,
in a plane containing the incident optical axis and orthogonal to the optical axis plane,
a second half-angle of incidence between the incident optical axis and the outer edge of the incident light is greater than 6 [deg] and equal to or smaller than the angle of incidence, and
NAx is greater than NAy when
NAx=sin (the second half-angle of incidence), and
NAy=sin (the first half-angle of incidence).

17. The inspection method according to claim 16, wherein
the projection optical system includes:
a concave mirror configured to reflect the reflected light from the inspection object, and
a spherical mirror configured to reflect the reflected light reflected by the concave mirror, and
the reflected light on a reflecting surface of the concave mirror is an ellipse, and
a proportion of a long axis to a short axis is approximately 0.5.

18. The inspection method according to claim 16, wherein
NAx is approximately twice NAy.
